(19) United States
(12) Patent Application Publication
(10) Pub. No.: US 2024/0090287 A1
(43) Pub. Date: Mar. 14, 2024

(54) DISPLAY PANEL AND DISPLAY DEVICE

(71) Applicant: XIAMEN TIANMA DISPLAY TECHNOLOGY CO., LTD., Xiamen (CN)

(72) Inventors: Huomei HUA, Xiamen (CN); Huangyao WU, Xiamen (CN)

(73) Assignee: XIAMEN TIANMA DISPLAY TECHNOLOGY CO., LTD., Xiamen (CN)

(21) Appl. No.: 18/508,199

(22) Filed: Nov. 13, 2023

(30) Foreign Application Priority Data
Jun. 12, 2023 (CN) 202310691721.0

(51) Int. Cl. H10K 59/131

(52) U.S. Cl. CPC H10K 59/131; H10K 2102/311

(57) ABSTRACT

A display panel and a display device are provided. The display panel includes: a display region; a non-display region surrounding at least a part of the display region, where the non-display region includes a first non-display region having a binding region and a bending region, and the bending region is located between the binding region and the display region; a first power signal line, located in the display region; and a first conductive layer, at least partly located in the first non-display region, configured to receive a first power signal, and connected to the first power signal line, where the first conductive layer includes a first hollow region between the bending region and the display region.

This application claims priority to Chinese Patent Application No. 202310691721.0, filed with the China National Intellectual Property Administration on Jun. 12, 2023 and entitled “DISPLAY PANEL AND DISPLAY DEVICE”, which is incorporated herein by reference in its entirety.

### FIELD

The present disclosure relates to the field of display technology, and specifically, to a display panel and a display device.

### BACKGROUND

With the continuous advancement of science and technology, more and more display devices are widely used in people's daily life and work, which bring great convenience to people's daily life and work, and have become an indispensable and important tool for people today.

The display panel is the main component of the display device to realize the display function. The display panel includes a display region and a frame region surrounding the display region. A display array for light emitting display is arranged in the display region, and a control chip for controlling a light emitting state of the display array is arranged in a non-display region.

Currently, the display panel has a problem of uneven display brightness, which affects an image display quality.

### SUMMARY

In view of the above, a display panel and a display device are provided according to the present disclosure.

One embodiment of the present disclosure provides a display panel, which includes:
a display region and a non-display region surrounding at least a part of the display region, where the non-display region includes a first non-display region, the first non-display region is located on a side of the display region, the first non-display region includes a binding region and a bending region, and the bending region is located between the binding region and the display region,
where the display panel further includes: a first power signal line, located in the display region; and a first conductive layer, where the first conductive layer is at least partly located in the first non-display region and configured to receive a first power signal, and the first power signal line is connected to the first conductive layer,
where a part of the first conductive layer between the bending region and the display region includes a first hollow region.

Another embodiment of the present disclosure provides a display device, which includes the above-described display panel.

### BRIEF DESCRIPTION OF DRAWINGS

In order to more clearly describe the embodiments of the present disclosure or the related art, the drawings used in the description of the embodiments or the conventional art are briefly described hereinafter. It is apparent that the drawings described merely shows some embodiments of the present disclosure, and that other drawings may be obtained.

The structures, scales and dimensions shown in the drawings of the specification are only used to cooperate with the content disclosed in the description, for those familiar with the art to understand and read, rather than limit the implementation of the present disclosure. Any modifications of the structures, changes of the scales and adjustments of the dimensions, if not impacting the effects and functions that can be achieve by the present disclosure.

FIG. 1 is a schematic structural diagram of a display panel.

FIG. 2 is a schematic structural diagram of a display panel according to an embodiment of the present disclosure.

FIG. 3 is a schematic structural diagram of another display panel according to an embodiment of the present disclosure.

FIG. 4 is a schematic structural diagram of yet another display panel according to an embodiment of the present disclosure.

FIG. 5 is a partial enlarged view of a display panel according to an embodiment of the present disclosure.

FIG. 6 is a partial enlarged view of another display panel according to an embodiment of the present disclosure.

FIG. 7 is a schematic diagram of a design of a first hollow region in a first conductive layer in a display panel according to an embodiment of the present disclosure.

FIG. 8 is a schematic diagram of a manner of region division in a display panel according to an embodiment of the present disclosure.

FIG. 9 is a partial enlarged view of yet another display panel according to an embodiment of the present disclosure.

FIG. 10 is a partial enlarged view of still another display panel according to an embodiment of the present disclosure.

FIG. 11 is a partial enlarged view of still another display panel according to an embodiment of the present disclosure.

FIG. 12 is a partial enlarged view of still another display panel according to an embodiment of the present disclosure.

FIG. 13 is a partial enlarged view of still another display panel according to an embodiment of the present disclosure.

FIG. 14 is a sectional view of the display panel shown in FIG. 13 in a Q-Q′ direction.

FIG. 15 is a schematic structural diagram of a display device according to an embodiment of the present disclosure.

### DESCRIPTION OF EMBODIMENTS

The embodiments according to the present disclosure are clearly and completely described hereinafter with reference to the accompanying drawings in embodiments of the present disclosure. It is apparent that the described embodiments are merely some rather than all of embodiments of the present disclosure. All other embodiments obtained by persons of ordinary skill in the art based on the embodiments according to the present disclosure.

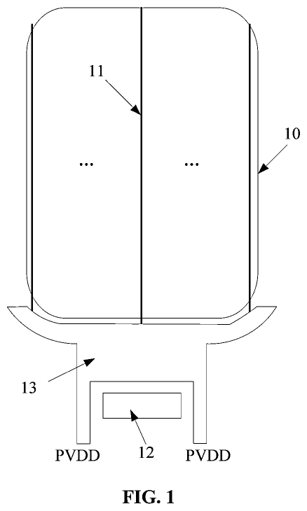

Referring to FIG. 1, FIG. 1 is a schematic structural diagram of a display panel. The display region 10 of the display panel includes multiple first power signal lines 11 arranged in parallel. The non-display region on one side of the display region 10 includes a binding region and a first conductive layer 13. The binding region is used for binding a control chip 12. Each of the multiple first power signal lines 11 in the display region 10 is connected to the first conductive layer 13 for receiving a first power signal PVDD through the first conductive layer 13.

In the display panel shown in FIG. 1, the conductive layer 13 between the binding region 12 and the display region 10 is a whole metal region. The two input terminals of the conductive layer 13 for receiving the first power signal PVDD are respectively located on both sides of the binding region 12. Since the first power signal PVDD transmitted in the conductive layer 13 has a different current path to each of the multiple first power signal lines 11 in the display region 10, and resistances of different current paths are different, resulting in different voltage drops in the multiple first power signal lines 11 and therefore display brightness differences in different parts of the display panel.

In view of this, embodiments of the present disclosure provide a display panel and a display device. The first conductive layer includes a first hollow region between the bending region and the display region of the display panel, and the current paths can be adjusted through the first hollow region, so that when the first power signal PVDD is input into different first power signal lines, the resistances of the current paths are the same or approximately the same, reducing the difference in voltage drop between different first power signal lines in the display region, and improving the brightness uniformity of the display region.

In order to make the embodiments of the present disclosure clearer and comprehensible, the present disclosure is further described in detail below in conjunction with the accompanying drawings and some embodiments.

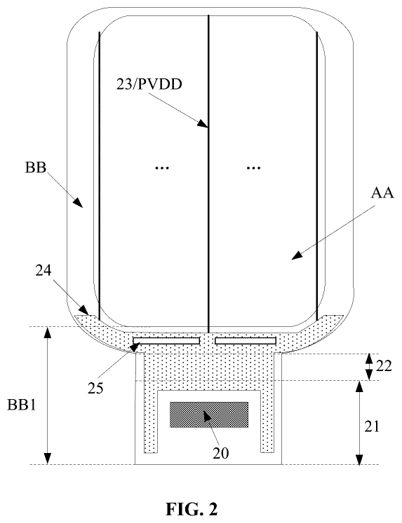

Referring to FIG. 2, FIG. 2 is a schematic structural diagram of a display panel according to an embodiment of the present disclosure. The display panel includes a display region AA and a non-display region BB surrounding at least a part of the display region AA. The non-display region BB includes a first non-display region BB1, which is located on one side of the display region AA. The first non-display region BB1 includes a binding region 21 and a bending region 22, and the bending region 22 is located between the binding region 21 and the display region AA.

As shown in FIG. 2, the display panel includes a first power signal line 23 and a first conductive layer 24. The first power signal line 23 is located in the display region AA. At least a part of the first conductive layer 24 is located in the first non-display region BB1. The first conductive layer 24 is configured to receive a first power signal PVDD. The first power signal line 23 is connected to the first conductive layer 24. A part of the first conductive layer 24, between the bending region 22 and the display region AA, includes a first hollow region 25.

The binding region 21 includes a pad for fixing the control chip 20. The binding region 21 can be flipped over to the back of the display panel by the bending region 22, to reduce a frame width of the first non-display region BB1.

In the embodiment shown in FIG. 2, the first conductive layer 24 includes a first hollow region 25 between the bending region 22 and the display region AA of the display panel. When a current is transmitted from the binding region 21 to different first power signal lines 23, the current can bypass the first hollow region 25. That is, the first hollow region 25 can change current paths, so that the first hollow region 25 can be used to make the lengths of the current paths the same or approximately the same, to ensure that the resistances corresponding to the current paths are the same or approximately the same, to reduce the difference in voltage drop between different first power signal lines in the display region, and improving the brightness uniformity of the display region.

In an embodiment of the present disclosure, the first conductive layer 24 may be located in a same conductive layer as a source and a drain of a transistor in the display region. It is easy to know that the display panel includes multiple metal layers, which are configured to prepare signal lines and other metal structures in a pixel circuit. Therefore, it is not limited to reusing the metal layer where the source and the drain are located to prepare the first conductive layer 24; rather, other metal layers in the display panel may alternatively be reused to prepare the first conductive layer 24. In some embodiments, the first conductive layer 24 may alternatively be formed by stacking multiple metal layers of the display panel, which is not limited here.

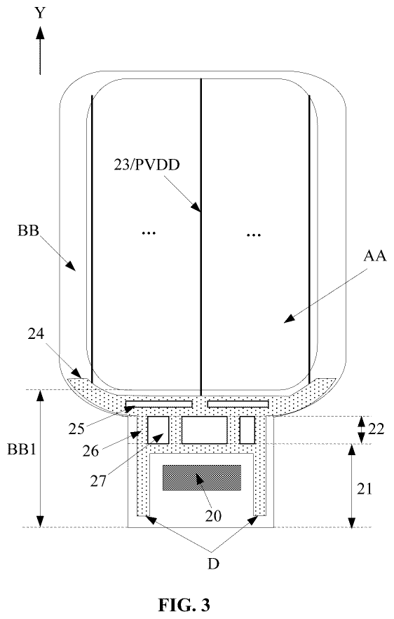

Referring to FIG. 3, FIG. 3 is a schematic structural diagram of another display panel according to an embodiment of the present disclosure. On the basis of the display panel shown in FIG. 2, in the display panel shown in FIG. 3, the display panel further includes a terminal D for receiving the first power signal PVDD at an end of the first non-display region BB1 away from the display region AA. The bending region 22 includes multiple wiring members 26 extending along a first direction Y, and the wiring members 26 are connected to the first conductive layer 24 and the terminal D. There is a second hollow region 27 between adjacent wiring members 26, and the first direction Y is an extending direction of the first power signal line 23.

In order to facilitate preparation process, the wiring members 26 and the first conductive layer 24 may be set on a same layer, and form an integral structure. In this way, the first conductive layer 24 and the wiring members 26 can be prepared simultaneously based on a same patterning process on a same conductive layer. In other embodiments, the wiring members 26 may alternatively be located on another metal layer than the first conductive layer 24.

The second hollow region 27 is provided in the bending region 22, which can improve a bendability of the conductive layer where the wiring members 26 are located, so that the conductive layer can be bent along with the bending region 24. Moreover, the second hollow region 27 can cooperate with the first hollow region 25 to adjust the current paths, to better regulate the voltage drops on different first power signal lines 23 and reduce the differences in voltage drop between different first power signal lines 23.

In the binding region 21, connection parts are provided on two sides of the control chip 20, respectively, where an end of the connection part is connected to the conductive layer where the wiring members 26 are located, and another end of the connection part is used as the terminal D for inputting the first power signal PVDD. An extending direction of the connecting parts is the same as the extending direction of the first power signal line 23.

In an embodiment, the first conductive layer 24, the wiring members 26 and the connecting part may form an integral structure, and be located in a same conductive layer, so that the first conductive layer 24, the wiring members 26 and the connecting part can be prepared simultaneously based on a same patterning process on a same conductive layer. In other embodiments, the first conductive layer 24, the wiring members 26 and the connecting part may alternatively be located in different conductive layers; or two of them are located in one conductive layer, while the other is located in another conductive layer.

The connecting part can extend a signal transmission path of the first power signal line 23, preventing the wiring members 26 from directly connecting to the first power signal line 23.

In an embodiment, the bending region 22 may include any number of wiring members 26, which is not limited to four wiring members 26 as shown in FIG. 3. In order to facilitate the preparation process, the bending region 22 may include three or four wiring members 26.

In an embodiment, as shown in FIG. 3, the wiring members 26 are arranged at equal intervals; that is, a distance between two adjacent wiring members 26 is uniform in the first direction Y. Line widths of the wiring members 26 are the same; that is, the line width of the wiring member 26 is uniform in the first direction Y. On one hand, this arrangement facilitates regulation of the resistance distribution and current paths of the conductive layer where the wiring members 26 are located, reduces the difference between voltage drops on different first power signal lines 23, and improves the uniformity of display brightness. On the other hand, this arrangement also enables the line width of the wiring member 26 to be uniform in the first direction Y, so that the corresponding second hollow region 27 is a rectangular structure, which facilitates the formation of the wiring members 26 and the second hollow region 27 with regular patterns on the conductive layer where the wiring members 26 are located, and facilitates the pattern design of the conductive layer.

In other embodiments, the wiring members 26 may alternatively be arranged at unequal intervals, and/or the wiring members 26 have different line widths.

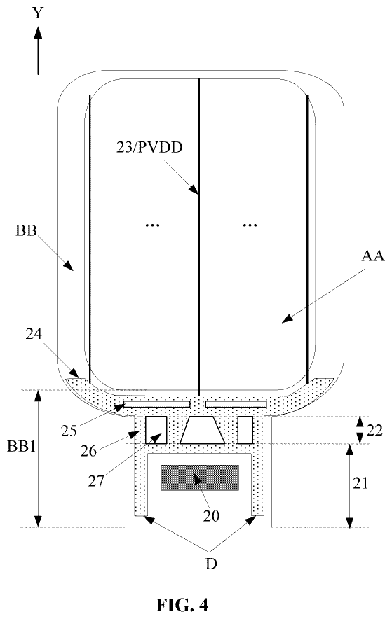

Referring to FIG. 4, FIG. 4 is a structural schematic diagram of yet another display panel according to an embodiment of this disclosure. The display panel shown in FIG. 4 differs from the display panel shown in FIG. 3 in that the second hollow region 27 thereof has a non-rectangular structure. As shown in FIG. 4, the second hollow region 27 of the non-rectangular structure is in the middle. The second hollow region 27 is of the non-rectangular structure so that the wiring members 26 on both sides of the second hollow region 27 are arranged at unequal intervals. In the first direction Y, the distance between the wiring members 26 on both sides of the second hollow region 27 of the non-rectangular structure of is non-uniform. As shown in FIG. 4, the second hollow region 27 of the non-rectangular structure has a trapezoidal structure, and the wiring members 26 on both sides of the second hollow region 27 are also trapezoidal structures. As shown in FIG. 4, the display panel further includes a second hollow region 27 of a rectangular structure, and wiring members 26 each of a rectangular structure with an equal line width.

The second hollow region 27 of the non-rectangular structure is not limited to the trapezoidal structure shown in FIG. 4, but may be structures having other geometrical patterns, such as triangular, circular, elliptical and circular structures. In an embodiment of the present disclosure, the shape of the second hollow region 27 may be set as needed, to form the wiring members 26 of a desired pattern. Patterns of the second hollow region 27 and the wiring members 26, the line width of the wiring member 26 and the spacing between the wiring members 26 related to the patterns are not limited in the embodiment of the present disclosure.

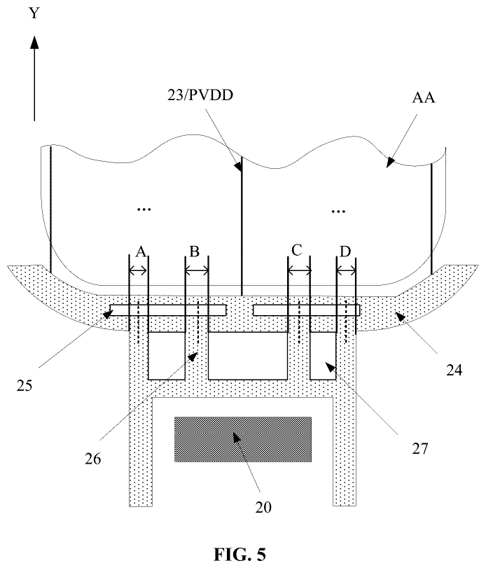

Referring to FIG. 5, FIG. 5 is a partial enlarged view of a display panel according to an embodiment of the present disclosure. On the basis of any of the above-described display panel embodiments, an extension line of the wiring member 26 intersects the first hollow region 25. In FIG. 5, an extension line of the wiring member 26 in the first direction Y is illustrated by a vertical dotted line.

As shown in FIG. 5, the extension line of the wiring member 26 intersects the first hollow region 25, which can prolong the current path from the wiring member 26 to the first power signal line 23 corresponding to the extension line of this wiring member 26. Here, the first power signal line 23 may be located in the four regions A, B, C, and D in FIG. 5. In the related art, the current path from the wiring member 26 to the first power signal line 23 in the four regions A, B, C, and D is relatively short; therefore voltage drops in these four regions are smaller, and corresponding display regions have higher brightness. In the embodiment of the present disclosure, the first hollow region 25 intersects the extension line of the wiring member 26, so that a current in the wiring member 26 is transmitted to the first power signal line 23 in the four regions A, B, C, and D after bypassing the first hollow region 25. In this way, the voltage drops can be increased by prolonging the current paths, to reduce the brightness of the display region corresponding to the extension line of the wiring member 26, to improve the display uniformity.

In an embodiment of the present disclosure, extension lines of multiple consecutively arranged wiring members 26 may intersect with a same first hollow region 25, where extension lines of two or three consecutively arranged wiring members 26 may intersect the same first hollow region 25. It is easy to know that extension lines of any number of consecutively arranged wiring members 26 may intersect the same first hollow region 25 as needed.

The extension lines of multiple consecutively arranged wiring members 26 are set to intersect the same first hollow region 25, so that the number of first hollow region 25 may be reduced to facilitate the formation of first hollow regions 25 on the first conductive layer 24, to simply a manufacturing process.

The current transmitted in each wiring member 26 can bypass both ends of the corresponding first hollow region 25 and then be transmitted to the corresponding first power signal line 23, to realize the adjustment of the current path. In a case that the extension lines of multiple consecutively arranged wiring members 26 intersect the same first hollow region 25, current path adjustment can be performed for the multiple consecutively arranged wiring members 26 based on the same first hollow region 25.

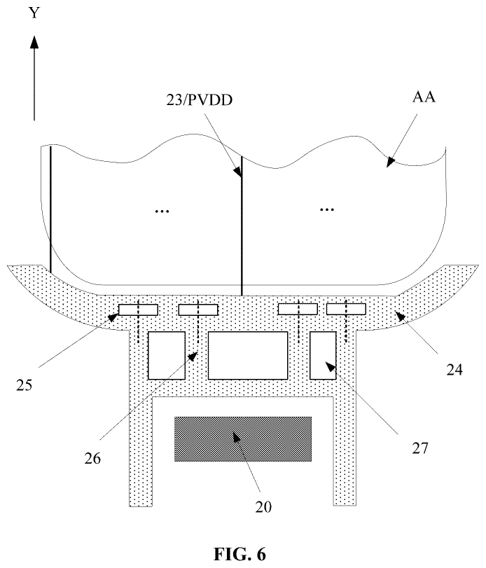

Referring to FIG. 6, FIG. 6 is a partial enlarged view of another display panel according to an embodiment of the present disclosure. The display panel shown in FIG. 6 differs from the display panel shown in FIG. 5 in that the extension line of each wiring member 26 thereof intersects a respective first hollow region 25. In this way, the extension line of each wiring member 26 intersects a respective first hollow region 25, so that the current path of the current transmitted in each wiring member 26 can be adjusted flexibly, and the resistance distribution of the first conductive layer 24 can also be adjusted flexibly, to reduce the difference between voltage drops on different first power signal lines 23 and improve the display brightness uniformity of the display region AA.

In a case that the extension line of the wiring member 26 intersects the first hollow region 25 in a one-to-one correspondence, an independent adjustment of the current path can be performed for each wiring member 26 through a respective first hollow region 25, which can reduce the difference between the voltage drops on different first power signal lines 23. Moreover, the extension line of the wiring member 26 may be an axis of symmetry of the first hollow region 25 it intersects, so that the current transmitted in the wiring member 26 can evenly bypass from both ends of the first hollow region 25, and then be transmitted to the corresponding first power signal line 23, which facilitates the regulation of the current path and resistance distribution, to achieve same current paths for different first power signal lines 23 to the greatest extent.

In this embodiment as shown in FIG. 5 and FIG. 6, the first hollow region 25 is a slit, for example, and an extending direction of the slit is perpendicular to the first direction Y. In practice, the geometry of the first hollow region 25 may be set as needed, and is not limited to the above-described slit. The first hollow region 25 may be a structure with any pattern, such as a regular polygon, a circle, an ellipse, and an irregular polygon, which is not limited in the embodiment of the present disclosure.

In the embodiment as shown in FIG. 5 and FIG. 6, the wiring member 26 extends in the first direction Y and has a constant line width, for example, and the corresponding second hollow region 27 is a rectangular structure. As noted above, the wiring members 26 may alternatively be arranged at unequal intervals, and/or the wiring members 26 may have different line widths.

In an embodiment, when the bending region 22 is not bent, in the first direction Y, the wiring member 26 passes through the entire bending region 22. That is, the second hollow region 27 passes through the entire bending region 22, so that the bending region 22 has good bending performance.

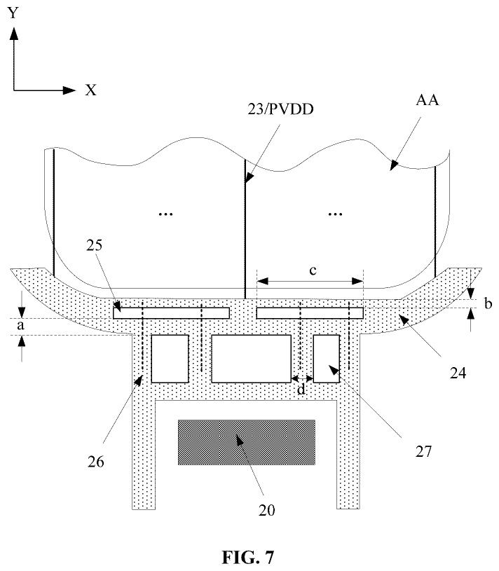

Referring to FIG. 7, FIG. 7 is a schematic diagram of a design of a first hollow region in a first conductive layer in a display panel according to an embodiment of the present disclosure. In the first direction Y, a first distance between an edge of the first hollow region 25 facing the display region AA and an edge of the first conductive layer 24 facing the display region AA is b, where the first distance b is not greater than 15 μm (microns). The first distance b is set to be not greater than 15 μm, which enables the first conductive layer 24 to have a sufficient area for arranging the first hollow region 25, and to facilitate the preparation of the first hollow region 25.

As shown in FIG. 7, a length c of the first hollow region 25 in a second direction X is greater than the line width d of the line segment 26. The first hollow region 25 includes a first end and a second end opposite to each other in the second direction X. The first end is a left end of the first hollow region 25 and the second end is a right end of the first hollow region 25 in FIG. 7. The intersection of the extension line of the wiring member 26 and a corresponding first hollow region 25 is between the first end and the second end. Here, the second direction X is perpendicular to the first direction Y, and in FIG. 7, the extension line of the wiring member 26 in the first direction Y is illustrated by a vertical dotted line.

In the embodiment as shown in FIG. 7, the intersection of the extension line of the wiring member 26 and the corresponding first hollow region 25 is between the first end and the second end, so that in the second direction X, each wiring member 26 can be located between the first end and the second end of the corresponding first hollow region 25. In this way, the current path can be adjusted for each wiring member 26 through the corresponding first hollow region 25, which can realize the adjustment of the resistance distribution of the first conductive layer 24, and reduce the difference between the voltage drops of different first power signal lines 23 to a large extent, and improve the display brightness uniformity of different regions in the display region AA.

As shown in FIG. 7, in the first direction Y, the edge of the first hollow region 25 facing the display region AA has a first distance b with the edge of the first conductive layer 24 facing the display region AA, and there is a second distance a between the first hollow region 25 and the wiring member 26.

In an embodiment, the first distance b may be set equal to the second distance a. In this embodiment, the first distance b is equal to the second distance, which is convenient for providing the first hollow region 25 in the first conductive layer 24 and simplifies the manufacturing process of the first hollow region 25.

In another embodiment, the second distance a is greater than the first distance b. In this way, the first hollow region 25 is closer to the display region AA to be farther away from the bending region 22, to prevent the first conductive layer 24 near the first hollow region 25 from breaking due to a stress generated when the bending region 22 is bent.

In a case that the second distance a is greater than the first distance b, the second distance a may be set to be greater than five times the first distance b. In this way, the second distance a can be much greater than the first distance b, which can better avoid the influence of the stress on the first conductive layer 24 near the first hollow region 25 when the bending region 22 is bent, to prevent the first conductive layer 24 near the first hollow region 25 from breaking.

It should be noted that the display panel shown in FIG. 7 is described on the basis of the display panel shown in FIG. 3. In practice, in the display panel according to any of the embodiments of the present disclosure, the first distance b, the second distance a, the length c, and the line width d in the first conductive layer 24 may all be configured according to the layout shown in FIG. 7. In a case that the first hollow region 25 and the second hollow region 27 are structures with irregular patterns, the first distance b, the second distance a, the length c and the line width d may all be respective average values.

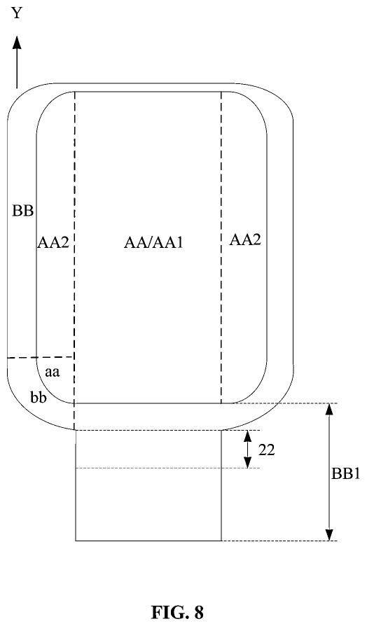

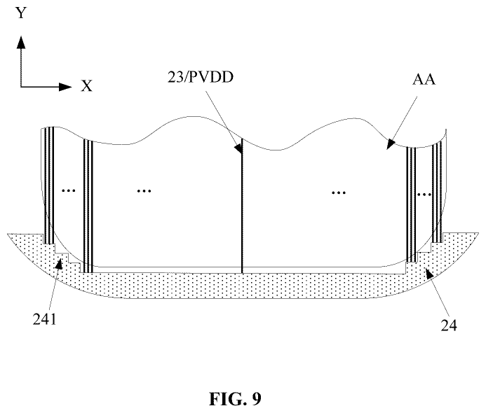

Referring to FIGS. 8 and 9, FIG. 8 is a schematic diagram of a manner of region division in a display panel according to an embodiment of the present disclosure, and FIG. 9 is a partial enlarged view of yet another display panel according to an embodiment of the present disclosure. In the embodiments as shown in FIG. 8 and FIG. 9, the display region AA includes a main display region AA1 and an irregularly-shaped display region AA2. A length of the irregularly-shaped display region AA2 in the first direction Y is less than a length of the main display region AA1 in the first direction Y. As noted above, the first direction Y is the extending direction of the first power signal lines 23. The irregularly-shaped display region AA2 includes an irregularly-shaped display sub-region aa close to the bending region 22, and an edge of the irregularly-shaped display sub-region aa is bent away from the display region AA. The non-display region BB includes an irregularly-shaped non-display region bb corresponding to the irregularly-shaped display sub-region aa. The first conductive layer 24 includes a part located in the irregularly-shaped non-display region bb, and the part of the first conductive layer 24 includes multiple step-like regions 241. Multiple first power signal lines 23 located in the irregularly-shaped display sub-region aa are electrically connected to the step-like regions 241.

For ease of illustration, FIG. 9 only shows the part of the first conductive layer 24 located between the bending region 22 and the display region AA, but does not show the above-described first hollow region 25, or the conductive layer in the bending region 22 and the binding region 21. The first conductive layer 24 with the step-like regions 241 shown in FIG. 9 may be applied to the display panel in any of the above-described embodiments.

In the embodiments shown in FIGS. 8 and 9, the part of the first conductive layer 24 corresponding to the irregularly-shaped display region AA2 includes multiple step-like regions 241, and multiple first power signal lines 23 arranged consecutively in the second direction in the irregularly-shaped display region AA2 are connected to a same step-like region 241, so that the multiple first power signal lines 23 connected to the same step-like region 241 have a small difference between contact resistances thereof with the first conductive layer 24, reducing the difference between the voltage drops of different first power signal lines 23, and improving the display brightness uniformity.

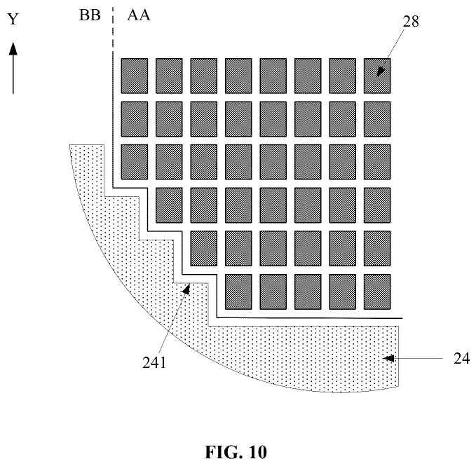

Referring to FIG. 10, FIG. 10 is a partial enlarged view of still another display panel according to an embodiment of the present disclosure, which shows a partial enlarged view of a lower left corner of the display panel in FIG. 8. As shown in FIGS. 8 to 10, the display region AA includes multiple pixel circuits 28, pixel circuits 28 at the edge of the irregularly-shaped display sub-region aa are distributed in a stepped manner, and the multiple step-like regions 241 match the distribution of the pixel circuits 28 at the edge of the irregularly-shaped display sub-region aa.

As shown in FIG. 8 and FIG. 10, the pixel circuits 28 at the edge of the irregularly-shaped display sub-region aa are arranged in a stepped manner, and the multiple step-like regions 241 are arranged to match the distribution of the pixel circuits 28 at the edge of the irregularly-shaped display sub-region aa, which can reduce the frame width at two top corners of the first non-display region BB1 of the display panel.

The pixel circuit 28 includes a transistor T and a storage capacitor C, and is configured to control the light emitting element to perform light emitting display. The pixel circuit 28 may be a circuit structure such as 7T1C or 8T1C. A specific implementation of the pixel circuit 28 is not limited in the embodiments of the present disclosure, and the pixel circuit 28 may be any pixel circuit structure in related art.

The pixel circuits 28 at the edge of the irregularly-shaped display sub-region aa are distributed in a stepped manner, and the multiple step-like regions 241 are arranged to match the distribution of the pixel circuits 28 at the edge of the irregularly-shaped display sub-region aa, so that the step-like regions 241 of the first conductive layer 24 and the pixel circuits 28 at the edge of the irregularly-shaped display sub-region aa can be nested with each other in a stepped distribution, and the frame width of the display panel in the irregularly-shaped non-display region bb can be reduced.

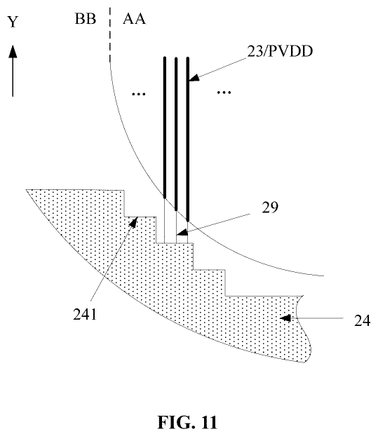

Referring to FIG. 11, FIG. 11 is a partial enlarged view of still another display panel according to an embodiment of the present disclosure, which shows a partial enlarged view of a lower left corner of the display panel in FIG. 8. As shown in FIG. 8, FIG. 9 and FIG. 11, the step-like region 241 is connected to the first power signal line 23 through at least one first connection line 29. The first connection line 29 can realize a connection between the first conductive layer 24 and the first power signal line 23. The first connection line 29 may be prepared by using an existing metal layer in the display panel to reduce the thickness of the panel.

In an embodiment of the present disclosure, the first connection line 29 may be located on a same conductive layer as the first power signal line 23 and the first conductive layer 24. The first connection line 29 is a part of the first power signal line 23 extending outside the display region AA, and is configured to realize an integrated connection with the first conductive layer 24. In this case, the first connection line 29, the first power signal line 23 and the first conductive layer 24 may be formed, as an integral structure, by a same conductive layer, to reduce the thickness of the display panel. In other embodiments, the first connection line 29 may be located in the same layer with the first conductive layer 24 or in different layers with the first conductive layer 24, and is located in a different layer from the first power signal line 23. In this case, the first power signal line 23 is connected to the first connection line 29 through a conductive hole, and the conductive hole connecting the first power signal line 23 to the first connection line 29 is located in the display region, which can reduce the frame width of the display panel.

In the two top corners of the first non-display region BB1, if one first connection line 29 is connected to multiple first power signal lines 23 at the same time, a current in the first connection line 29 is a sum of currents of the multiple first power signal lines 23 since each first power signal line 23 has a current. In a case that the first connection line 29 is connected to too many first power signal lines 23, the current in the first connection line 29 will be too large, resulting in a large voltage drop in the two top corners of the first non-display region BB1. As a consequence, a middle region of the display region AA has large brightness, and a marginal region of the display region AA near the two top corners has small brightness, to cause a large brightness difference between the middle region and the marginal region on both sides of the display region AA. In order to solve this problem, in an embodiment of the present disclosure, one first connection line 29 is provided to connect the step region 241 to the first power signal line 23, or one first connection line 29 is connected to N first power signal lines 23 located in the irregularly-shaped display region AA2, where N is a positive integer less than 8, to reduce the voltage drop at the two top corners of the first non-display region BB1, to reduce the brightness difference between the middle region and the marginal region on both sides of the display region AA.

In an embodiment, as shown in FIG. 11, the step-like region 241 and the first power signal line 23 is connected through a respective first connection line 29. As noted above, in a case that the step-like region 241 is connected to the first power signal line 23 through the respective first connecting line 29, the voltage drop at the two top corners of the first non-display region BB1 can be reduced to the greatest extent, to reduce the brightness difference between the middle region and the marginal region on both sides of the display region AA.

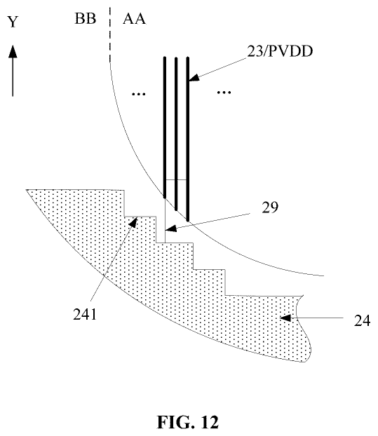

Referring to FIG. 12, FIG. 12 is a partial enlarged view of still another display panel according to an embodiment of the present disclosure, which shows a partial enlarged view of a lower left corner of the display panel in FIG. 8. As shown in FIG. 8, FIG. 9 and FIG. 12, one first connection line 29 is connected to multiple first power signal lines 23 located in the irregularly-shaped display region AA2 to reduce the voltage drop at the two top corners of the first non-display region BB1. In an embodiment, one first connecting line 29 may be connected to N first power signal lines 23 located in the irregularly-shaped display region AA2, where N is a positive integer less than 8. As noted above, in this way, the voltage drop at the two top corners of the first non-display region BB1 can be reduced, to reduce the brightness difference between the middle region and the marginal on both sides of the display region AA.

In an embodiment of this disclosure, the value of N may be set as needed, for example, N may be five, or four, or three.

In an embodiment, a line width of the first connection line 29 is larger than 15 μm. Generally, due to requirements for layout space of the pixel circuits and light emitting elements in the display region AA, the first power signal line 23 in the display region AA has a small line width, where the line width of the first power signal line 23 is generally less than 15 μm. Compared with the first power signal line 23, wiring space of the first connection line 29 located in the non-display region BB is relatively sufficient in the second direction X, so the line width of the first connection line 29 may be set to be greater than 15 μm to reduce the impedance of a loop including the first connection line 29 and the first power signal line 23. In a case that the first connection line 29 and the first power signal line 23 are in different layers, the first power signal line 29 with a large line width can also reduce a contact impedance with the first power signal line 23.

In an embodiment of this disclosure, the first hollow region 25 may be provided in the first conductive layer 24; or the first hollow region 25 is provided in the first conductive layer 24 and the second hollow region 27 is provided in a conductive layer where the wiring members 26 are located. In this way, the current path in the conductive layer of the first non-display region BB1 for transmitting the first power signal PVDD can be adjusted, so that different first power signal lines 23 in the display region AA have the same or similar voltage drops, to improve the display brightness uniformity of a row of light emitting elements in the display region AA along the second direction X.

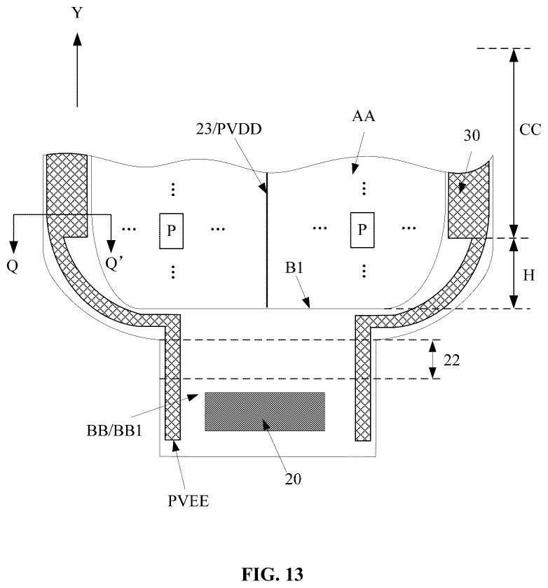

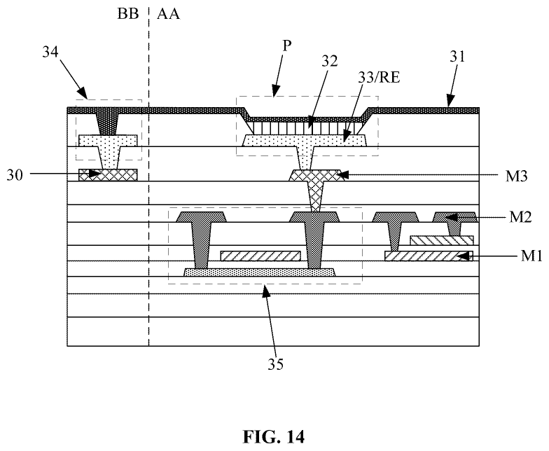

There are light emitting elements arranged in an array in the display region AA. The anodes of the light emitting elements are connected to the pixel circuits, and the pixel circuits receive the first power signal PVDD through the first power signal lines 23. Pixel circuits connected to a column of light emitting elements arranged along the first direction Y are all connected to a same first power signal line. For any first power signal line 23, the voltage drop on the first power signal line 23 can cause the first power signal PVDD received by the corresponding column of pixel circuits to have a voltage drop in the first direction Y, and along the first direction Y, in the column of light emitting elements connected to the same first power signal line 23, a light emitting element closer to the control chip 20 has a larger display brightness than a light emitting element farther away from the control chip 20. In order to solve this problem, the designs shown in FIGS. 13 and 14 can be used.

Referring to FIGS. 13 and 14, FIG. 13 is a partial enlarged view of still another display panel according to an embodiment of the present disclosure, and FIG. 14 is a sectional view of the display panel shown in FIG. 13 in a Q-Q′ direction. On the basis of any of the above-described embodiments, in this embodiment, the non-display region BB includes a cathode connection region CC surrounding at least a part of the display region AA. The first non-display region BB1 is adjacent to a first side edge B1 of the display region AA. In the first direction Y, the cathode connection region CC is located on a side of the first side edge B1 facing away from the bending region 22, and has a preset distance H from the first side edge B1.

The display panel further includes a second conductive layer 30 and multiple light emitting elements P. At least a part of the second conductive layer 30 is located in the cathode connection region CC, and the second conductive layer 30 is configured to receive a second power signal PVEE. The multiple light emitting elements P share a common cathode 31. The common cathode 31 and the second conductive layer 30 are connected in the cathode connection region CC. As noted above, the first direction Y is the extending direction of the first power signal line 23.

Generally, the second conductive layer 30 includes two ends in the first non-display region BB1, for receiving the second power signal PVEE, and a part between the two ends surrounds the non-display region BB and another part between the two ends surrounds the display region AA. For example, the first non-display region BB1 is a lower non-display region, and the second conductive layer 30 surrounds a left side and a right side of the lower non-display region and an upper display region. In this way, the second conductive layer 30 not only can be used for inputting the second power signal PVEE, but also can realize electrostatic protection for surrounded metal structures and protect the metal structures from being damaged by static electricity.

In the display panel, the first power signal PVDD is transmitted from an end close to the control chip 20 to an end far away from the control chip 20. Since there is a voltage drop in the first power signal line 23 and the first power signal PVDD is a positive voltage, the first power signal PVDD corresponding to a light emitting element closer to the control chip 20 is greater than the first power signal PVDD corresponding to a light emitting element farther away from the control chip 20. For the second conductive layer 30 connected to the second power signal PVEE, there is also a voltage drop thereon, and the second power signal PVEE is a negative voltage; hence, the second power signal PVEE corresponding to a light emitting element closer to the control chip 20 is smaller than the second power signal PVEE corresponding to a light emitting element farther away from the control chip 20. It should be noted that the brightness of the light emitting element is related to the difference between the first power signal PVDD and the second power signal PVEE inputted to the light emitting element. Therefore, based on a change rule of the first power signal PVDD and the second power signal PVEE, it can be known that a difference V1 between the first power signal PVDD and the second power signal PVEE corresponding to a light emitting element closer to the control chip 20 is greater than a difference V2 between the first power signal PVDD and the second power signal PVEE corresponding to a light emitting element farther away from the control chip 20. For example, the first power signal PVDD corresponding to the light emitting element closer to the control chip 20 is 2.8V, the second power signal PVEE is −3.5V, and the difference V1 between them is 6.3V. The first power signal PVDD corresponding to the light emitting element farther away from the control chip 20 is 2.4V, the second power signal PVEE is −3.2V, and the difference V2 between them is 5.6V. In this way, the brightness of the light emitting element closer to the control chip 20 is greater than the brightness of the light emitting element farther away from the control chip 20, resulting in uneven display.

In the embodiment of the present disclosure, a distance between the cathode connection region CC and the first side edge B1 is set to a preset distance H. That is, the cathode connection region CC is not located in the irregularly-shaped non-display region bb, by which the common cathode 31 and the second conductive layer 30 are connected to each other in area region far from an input terminal for the second power signal PVEE. In this way, the second power signal PVEE corresponding to the light emitting element closer to the control chip can be increased, for example, from −3.5V to −3.3V, so that the difference V1 between the first power signal PVDD and the second power signal PVEE corresponding to the light emitting element closer to the control chip 20 decreases, for example, to 6.1V. In this way, a difference between V1 and V2 can be reduced, to reduce the difference in brightness between the two light emitting elements, and alleviating the problem of uneven display of the display panel.

The display panel is an OLED display panel, and the light emitting element P is an OLED. The light emitting element P includes an anode 33 on an array substrate, an organic light emitting layer 32 on the anode 33, and a common cathode 31 on the organic light emitting layer 32. The anode 33 is located in an anode metal layer RE. The anode of the light emitting element P is connected to the pixel circuit 28 in the array substrate. The pixel circuit 28 includes a transistor 35.

A gate of the transistor 35 is located in a first metal layer M1, a source and drain thereof are located in a second metal layer M2, and the second metal layer M2 is located between the first metal layer M1 and the anode metal layer RE. There is also a third metal layer M3 between the anode metal layer RE and the second metal layer M2 for arranging some signal lines connected to the pixel circuit.

The second conductive layer 30 may be prepared by using an existing metal layer in the display panel. For example, the second conductive layer 30 may be prepared by using the third metal layer M3 or the second metal layer M2. In FIG. 14 the second conductive layer 30 is prepared by using the third layer M3. In the embodiment of the present disclosure, there is no limitation on a metal layer reused as the second conductive layer 30.

The second conductive layer 30 is connected to the common cathode 31 through an electrical connection structure 34. The electrical connection structure 34 includes a conductive via hole between the second conductive layer 30 and the common cathode 31. In a case that there is another metal layer between the common cathode 31 and the metal layer where the second conductive layer 30 is located, a transfer metal block may be provided in the cathode connection region CC by using this another metal layer, to reduce a depth of the conductive via hole between the second conductive layer 30 and the common cathode 31.

As shown in FIG. 8 and FIG. 13, the display region AA includes a main display region AA1 and an irregularly-shaped display region AA2. A length of the irregularly-shaped display region AA2 in the first direction Y is less than a length of main display region AA1 in the first direction Y. The irregularly-shaped display region AA2 includes an irregularly-shaped display sub-region aa close to the bending region 22, and an edge of the irregularly-shaped display sub-region aa is bent away from the display region AA. The first non-display region BB1 includes an irregularly-shaped non-display region bb corresponding to the irregularly-shaped display sub-region aa. An edge of the irregularly-shaped non-display region bb away from the display region AA is an arc with a radius R, where the preset distance H is not less than half of R. According to simulation test data, a display brightness difference between a light emitting element closer to the control chip 20 and a light emitting element farther away from the control chip 20, among a column of light emitting elements corresponding to a same power signal line 23, can be well reduced in the first direction Y based on the preset distance H with such configured values.

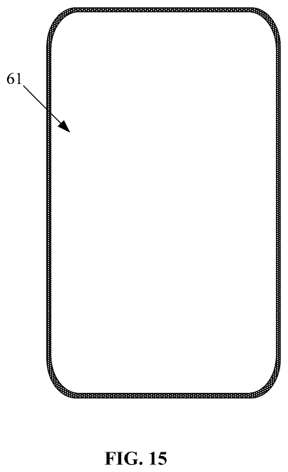

Based on the above embodiments, a display device is further provided according to another embodiment of the present disclosure, as shown in FIG. 15.

Referring to FIG. 15, FIG. 15 is a schematic structural diagram of a display device according to an embodiment of the present disclosure. The display device includes a display panel 61 described in any of the above embodiments, and the display panel has a good display uniformity. Compared with a display device with a conventional display panel, the display device including the display panel 61 according to the embodiments of the present disclosure can improve the uniformity of display brightness by 5%.

The display device includes a circuit board located on a side of the display panel 61 facing away from a display surface. The input terminal of the first power signal PVDD and the input terminal of the second power signal PVEE may be connected to the circuit board through a flexible printed circuit (FPC), to input the first power signal PVDD and the second power signal PVEE respectively.

The display devices may be a mobile phone, a tablet computer, a vehicle-mounted display device, or a wearable device with display functions.

The embodiments in this specification are described in a progressive manner, in parallel, or in a progressive-parallel-combined manner. Each embodiment focuses on the differences from the other embodiments, and reference may be made to each other for the same or similar parts.

It should be noted that, in the description of the present disclosure, it should be understood that the descriptions of the drawings and embodiments are illustrative rather than restrictive. The same reference numerals identify the same structures throughout the embodiments of the specification. In addition, for the sake of understanding and ease of description, the thickness of some layers, films, panels, regions, etc. may be exaggerated in the drawings. Also, it will be understood that when an element such as a layer, film, region, or substrate is referred to as being “on” another element, it can be directly on the other element or intervening elements may be present. In addition, “on” means positioning an element on or under another element, but does not essentially mean positioning on an upper side of another element according to the direction of gravity.

The orientation or positional relationship indicated by the terms “upper”, “lower”, “top”, “bottom”, “inner”, “outer”, etc. is based on the orientation or positional relationship shown in the drawings, and is only for the convenience of describing the present disclosure and simplified descriptions, rather than indicating or implying that the device or element referred to must have a specific orientation, or be constructed and operate in a specific orientation, and thus should not be construed as limiting the disclosure. When a component is said to be “connected” to another component, it may be directly connected to the other component or there may be an intervening component.

It should also be noted that in this disclosure, relational terms such as first and second etc. are only used to distinguish one entity or operation from one another, and do not necessarily require or imply that these entities or operations has any such actual relationship or sequence therebetween. Moreover, the term “include”, “comprise” or any other variation thereof is intended to cover a non-exclusive inclusion and an article or device comprising a set of elements includes not only those elements but also other elements not expressly listed, or also include elements inherent to the article or device. Without further limitations, an element defined by the phrase “comprising a . . . ” does not exclude the presence of additional identical elements in an article or device comprising the aforementioned element.

The above description of the disclosed embodiments is provided to enable any person skilled in the art to make or use the present disclosure. Various modifications to these embodiments will be readily apparent to those skilled in the art, and the general principles defined herein may be implemented in other embodiments without departing from the spirit or scope of the disclosure. Therefore, the present disclosure will not be limited to the embodiments described herein, but is to be accorded the widest scope consistent with the principles and novel features disclosed herein.

What is claimed is:

1. A display panel, comprising:
a display region;
a non-display region surrounding at least a part of the display region, wherein the non-display region comprises a first non-display region located on a side of the display region, the first non-display region comprises a binding region and a bending region, and the bending region is located between the binding region and the display region;
a first power signal line, located in the display region; and
a first conductive layer, wherein the first conductive layer is at least partly located in the first non-display region and configured to receive a first power signal, and the first power signal line is connected to the first conductive layer,
wherein a part of the first conductive layer between the bending region and the display region comprises a first hollow region.

2. The display panel according to claim 1, further comprising a terminal, at an end of the first non-display region away from the display region, for receiving the first power signal,
wherein the bending region comprises a plurality of wiring members extending along a first direction, and the plurality of wiring members is connected to the first conductive layer and the terminal, and
there is a second hollow region between adjacent wiring members, and the first direction is an extending direction of the first power signal line.

3. The display panel according to claim 2, wherein the plurality of wiring members is arranged at equal intervals, and line widths of the plurality of wiring members are the same.

4. The display panel according to claim 2, wherein an extension line of the wiring member intersects the first hollow region.

5. The display panel according to claim 4, wherein an extension line of each of the plurality of wiring members intersects a respective first hollow region.

6. The display panel according to claim 4, wherein extension lines of a plurality of consecutively arranged wiring members intersect a same first hollow region.

7. The display panel according to claim 4, wherein there is a first distance between an edge of the first hollow region facing the display region and an edge of the first conductive layer facing the display region in the first direction, and the first distance is not greater than 15 μm.

8. The display panel according to claim 4, wherein a length of the first hollow region in a second direction is greater than a line width of the wiring member,
the first hollow region comprises a first end and a second end opposite to the first end in the second direction,
an intersection of the extension line of the wiring member and a corresponding first hollow region is between the first end and the second end, and the second direction is perpendicular to the first direction.

9. The display panel according to claim 4, wherein there is a first distance between an edge of the first hollow region facing the display region and an edge of the first conductive layer facing the display region in the first direction, and there is a second distance between the first hollow region and the wiring member,
wherein the first distance is equal to the second distance.

10. The display panel according to claim 4, wherein there is a first distance between an edge of the first hollow region facing the display region and an edge of the first conductive layer facing the display region in the first direction, and there is a second distance between the first hollow region and the wiring member,
wherein the second distance is greater than the first distance.

11. The display panel according to claim 10, wherein the second distance is greater than five times the first distance.

12. The display panel according to claim 1, wherein the display region comprises a main display region and an irregularly-shaped display region, a length of the irregularly-shaped display region in a first direction is smaller than a length of the main display region in the first direction, and the first direction is an extending direction of the first power signal line;
the irregularly-shaped display region comprises an irregularly-shaped display sub-region close to the bending region, and an edge of the irregularly-shaped display sub-region is bent away from the display region;
the non-display region comprises an irregularly-shaped non-display region corresponding to the irregularly-shaped display sub-region; and
the first conductive layer comprises a part located in the irregularly-shaped non-display region, the part of the first conductive layer comprises a plurality of step-like regions, and a plurality of first power signal lines located in the irregularly-shaped display region is electrically connected to the plurality of step-like regions.

13. The display panel according to claim 12, wherein the display region comprises a plurality of pixel circuits, and a plurality of pixel circuits at the edge of the irregularly-shaped display sub-region is distributed in a stepped manner, and the plurality of step-like regions matches a distribution of the plurality of pixel circuits at the edge of the irregularly-shaped display sub-region.

14. The display panel according to claim 12, wherein the plurality of step-like regions is connected to the plurality of first power signal line through at least one first connection line.

15. The display panel according to claim 14, wherein one first connection line is connected to N first power signal lines located in the irregular-shaped display region, and N is a positive integer less than 8.

16. The display panel according to claim 15, wherein a line width of the first connecting line is greater than 15 μm.

17. The display panel according to claim 1, wherein the non-display region comprises a cathode connection region at least surrounding a part of the display region, the first non-display region is adjacent to a first side edge of the display region;
the cathode connection region is located on a side of the first side edge facing away from the bending region in a first direction, and there is a preset distance between the cathode connection region and the first side edge; and
the display panel further comprises:
a second conductive layer, at least partly located in the cathode connection region, and configured to receive a second power signal, and
a plurality of light emitting elements, where the plurality of light emitting elements shares a common cathode, and the common cathode and the second conductive layer are connected in the cathode connection region,
wherein the first direction is an extending direction of the first power signal line.

18. The display panel according to claim 17, wherein the display region comprises a main display region and an irregularly-shaped display region, and a length of the irregularly-shaped display region in the first direction is smaller than a length of the main display region in the first direction;
the irregularly-shaped display region comprises an irregularly-shaped display sub-region close to the bending region, and an edge of the irregularly-shaped display sub-region is bent away from the display region; and
the first non-display region comprises an irregularly-shaped non-display region corresponding to the irregularly-shaped display sub-region, an edge of the irregularly-shaped non-display region away from the display region is an arc with a radius R, and the preset distance is not less than half of R.

19. A display device, comprising:
a display panel,
the display panel comprising:
a display region;
a non-display region surrounding at least a part of the display region, wherein the non-display region comprises a first non-display region, the first non-display region is located on a side of the display region, the first non-display region comprises a binding region and a bending region, and the bending region is located between the binding region and the display region;
a first power signal line, located in the display region; and
a first conductive layer, wherein the first conductive layer is at least partly located in the first non-display region and configured to receive a first power signal, and the first power signal line is connected to the first conductive layer,
wherein a part of the first conductive layer between the bending region and the display region comprises a first hollow region.

20. The display device according to claim 19, wherein the display panel further comprises:
a terminal, at an end of the first non-display region away from the display region, for receiving the first power signal,
wherein the bending region comprises a plurality of wiring members extending along a first direction, and the plurality of wiring members is connected to the first conductive layer and the terminal, and
there is a second hollow region between adjacent wiring members, and the first direction is an extending direction of the first power signal line.
